(19) United States
(12) Patent Application Publication
(10) Pub. No.: US 2025/0125090 A1
(43) Pub. Date: Apr. 17, 2025

(54) MULTILAYER CERAMIC CAPACITOR, PACKAGE, AND CIRCUIT BOARD

(71) Applicant: TAIYO YUDEN CO., LTD., Tokyo (JP)

(72) Inventor: Ayumi SHIROTA, Tokyo (JP)

(73) Assignee: TAIYO YUDEN CO., LTD., Tokyo (JP)

(21) Appl. No.: 18/984,407

(22) Filed: Dec. 17, 2024

Related U.S. Application Data
(63) Continuation of application No. PCT/JP2023/023184, filed on Jun. 22, 2023.

(30) Foreign Application Priority Data
Jul. 5, 2022 (JP) 2022-108417

(51) Int. Cl. H01G 2/06; H01G 4/008; H01G 4/012; H01G 4/12; H01G 4/232; H01G 4/30; H05K 1/18

(52) U.S. Cl. CPC H01G 2/065; H01G 4/008; H01G 4/012; H01G 4/12; H01G 4/2325; H01G 4/30; H05K 1/181; H05K 2201/10015

(57) ABSTRACT

A multilayer ceramic capacitor has a dimension in a first direction equal to or greater than 1.5 times a dimension in a second direction orthogonal to the first direction, and includes a ceramic body, which has main surfaces perpendicular to the first direction, an end surface perpendicular to a third direction orthogonal to the first and second directions, and internal electrodes mainly composed of Ni, stacked in the second direction, and led out to respective connection ends on the end surface, and an external electrode, which is mainly composed of Cu and covers the end surface. The internal electrodes include outer-side internal electrodes located in both outer sides and inner-side internal electrodes located an inner side in the second direction. Distances from the main surfaces are larger at the connection ends of the outer-side internal electrodes than in central portions in the third direction of the inner-side internal electrodes.

### CROSS-REFERENCE TO RELATED APPLICATION

This application is a continuation application of PCT/JP2023/023184 filed on Jun. 22, 2023, which claims priority to Japanese Patent Application No. 2022-108417 filed on Jul. 5, 2022, the entire contents of which are incorporated herein by reference.

### FIELD

A certain aspect of the present disclosure relates to a multilayer ceramic capacitor, a package, and a circuit board.

### BACKGROUND

International Publication No. 2014/175034 (Patent Document 1) describes a phenomenon in which, when external electrodes containing Cu as a main component are fired on a ceramic body having internal electrodes containing Ni as a main component, Cu contained in the external electrodes diffuses into the internal electrodes while reacting with Ni. This phenomenon causes expansion of the end portions, which are close to the external electrodes, of the internal electrodes in the ceramic body.

In the ceramic body, only the section adjacent to the external electrode tends to expand in the stacking direction due to the expansion of the internal electrodes. In the ceramic body, internal stress generated by the expansion concentrates on the corner portions, and thus cracks are likely to be generated. Such cracks are more likely to be generated in a tall structure having a large number of internal electrodes stacked.

In the multilayer ceramic capacitor, it is effective to decrease the firing temperature of the external electrodes to the ceramic body in order to inhibit the diffusion of Cu contained in the external electrodes into the internal electrodes. That is, by lowering the firing temperature, the reaction rate between Cu and Ni is reduced, and thus, the diffusion of Cu into the internal electrode can be inhibited.

### SUMMARY

However, when the firing temperature of the external electrodes to the ceramic body is lowered, it is difficult to obtain sufficient sintering of the external electrodes. As a result, in the multilayer ceramic capacitor, problems such as degradation in long-term reliability due to a decrease in the denseness of the external electrode and insufficient connection strength of the external electrode to the ceramic body are likely to occur.

In view of the above circumstances, it is an object of the present disclosure to provide a multilayer ceramic capacitor, a package, and a circuit board that are capable of inhibiting the generation of cracks in a ceramic body with a tall structure.

A multilayer ceramic capacitor according to an embodiment of the present disclosure has a dimension in a first direction along a first axis equal to or greater than 1.5 times a dimension in a second direction along a second axis orthogonal to the first axis, and is to be mounted on a mounting surface perpendicular to the first axis.

The multilayer ceramic capacitor includes a ceramic body and an external electrode.

The ceramic body has a pair of main surfaces perpendicular to the first axis, an end surface perpendicular to a third axis orthogonal to the first axis and the second axis, and a plurality of internal electrodes that contain Ni as a main component, are stacked in the second direction, and are led out to respective connection ends on the end surface.

The external electrode contains Cu as a main component and covers the end surface.

The internal electrodes include outer-side internal electrodes located in both outer sides in the second direction and inner-side internal electrodes located in an inner side in the second direction.

Respective distances from the pair of main surfaces at the connection end of each of the outer-side internal electrodes are larger than respective distances from the pair of main surfaces at a center of each of the inner-side internal electrodes in a third direction along the third axis.

A multilayer ceramic capacitor according to an embodiment of the present disclosure has a dimension in a first direction along a first axis equal to or greater than 1.3 times a dimension in a second direction along a second axis orthogonal to the first axis, and is to be mounted on a mounting surface perpendicular to the first axis.

The multilayer ceramic capacitor includes a ceramic body and an external electrode.

The ceramic body has a pair of main surfaces perpendicular to the first axis, an end surface perpendicular to a third axis orthogonal to the first axis and the second axis, and a plurality of internal electrodes that contain Ni as a main component, are stacked in the second direction, and are led out to respective connection ends on the end surface.

The external electrode contains Cu as a main component and covers the end surface.

The internal electrodes include outer-side internal electrodes located in both outer sides in the second direction and inner-side internal electrodes located in an inner side in the second direction.

Respective distances from the pair of main surfaces at the connection end of each of the outer-side internal electrodes are larger than respective distances from the pair of main surfaces at a central of each of the inner-side internal electrodes in a third direction along the third axis.

In this multilayer ceramic capacitor, in a tall structure having a larger dimension in the height direction, the stacking direction of the internal electrodes in the ceramic body is set to the width direction having a smaller dimension, and thus the number of stacked internal electrodes can be reduced without a decrease in electrostatic capacitance. This allows the amount of expansion of the internal electrodes due to the diffusion of Cu contained in the external electrodes to be reduced as a whole in the ceramic body, and thus, the stress applied to the corner portions is reduced.

In addition, in the ceramic body, the connection ends of the internal electrodes are provided away from the pair of main surfaces in the corner portions, that is, the internal electrodes are disposed so as to avoid the corner portions of the ceramic body. Accordingly, in the ceramic body, stress is less likely to be concentrated on the corner portion where the internal electrodes are not disposed.

With such a configuration, in the multilayer ceramic capacitor, the generation of cracks in the corner portions of the ceramic body can be effectively inhibited.

Each of the internal electrodes may have larger distances from the pair of main surfaces at the connection end than in the central portion in the third direction.

The respective distances from the pair of main surfaces may be larger than those in the central portion of each of the inner-side internal electrodes in the third direction throughout each of the outer-side internal electrodes in the third direction.

The respective distances from the pair of main surfaces at the connection end of each of the outer-side internal electrodes may be larger than respective distances from the pair of main surfaces at the connection end of each of the inner-side internal electrodes.

A package according to an embodiment of the present disclosure includes the above multilayer ceramic capacitor, a carrier tape, and a top tape.

The carrier tape has a sealing surface perpendicular to the first axis, and a recess that is recessed from the sealing surface in the first direction and accommodates the multilayer ceramic capacitor.

The top tape is attached to the sealing surface and covers the recess.

A circuit board according to an embodiment of the present disclosure includes the above multilayer ceramic capacitor and a mounting substrate.

The mounting substrate has a mounting surface perpendicular to the first axis, and a connection electrode provided on the mounting surface and connected to the external electrode of the multilayer ceramic capacitor through solder.

### BRIEF DESCRIPTION OF THE DRAWINGS

FIG. 1 is a perspective view of a multilayer ceramic capacitor according to a first embodiment;

FIG. 2 is a cross-sectional view of the multilayer ceramic capacitor taken along the line A1-A1′ in FIG. 1;

FIG. 3 is a cross-sectional view of the multilayer ceramic capacitor taken along line B1-B1′ in FIG. 1;

FIG. 4 is a cross-sectional view of the multilayer ceramic capacitor taken along the line A2-A2′ in FIG. 1;

FIG. 5 is a cross-sectional view of the multilayer ceramic capacitor taken along line B2-B2′ in FIG. 1;

FIG. 6 is a partially exploded view of the ceramic body of the multilayer ceramic capacitor;

FIG. 7 is a flowchart illustrating a method of manufacturing the multilayer ceramic capacitor;

FIG. 8A, FIG. 8B, and FIG. 8C are plan views of ceramic sheets prepared in step S01;

FIG. 9 schematically illustrates step S02;

FIG. 10 is a plan view illustrating step S03;

FIG. 11 is a side view of a circuit board including the multilayer ceramic capacitor;

FIG. 12 is a partial plan view of a package of the multilayer ceramic capacitor;

FIG. 13 is a cross-sectional view of the package taken along line C-C′ in FIG. 11;

FIG. 14 is a cross-sectional view of a multilayer ceramic capacitor in accordance with a second embodiment, taken along line A2-A2′ in FIG. 1;

FIG. 15 is a cross-sectional view of the multilayer ceramic capacitor taken along line B2-B2′ in FIG. 1;

FIG. 16 is a partially exploded view of the ceramic body of the multilayer ceramic capacitor;

FIG. 17 is a cross-sectional view of a multilayer ceramic capacitor in accordance with a third embodiment, taken along line A1-A1′ in FIG. 1;

FIG. 18 is a cross-sectional view of the multilayer ceramic capacitor taken along line B2-B2′ in FIG. 1; and

FIG. 19 is a partially exploded view of the ceramic body of the multilayer ceramic capacitor.

### DETAILED DESCRIPTION

Hereinafter, a multilayer ceramic capacitor 10 according to an embodiment of the present disclosure will be described with reference to the drawings. In the drawings, an X-axis, a Y-axis, and a Z-axis orthogonal to each other are illustrated as appropriate. The X-axis, the Y-axis, and the Z-axis define a fixed coordinate system fixed with respect to the multilayer ceramic capacitor 10.

### First Embodiment

### Structure of Multilayer Ceramic Capacitor 10

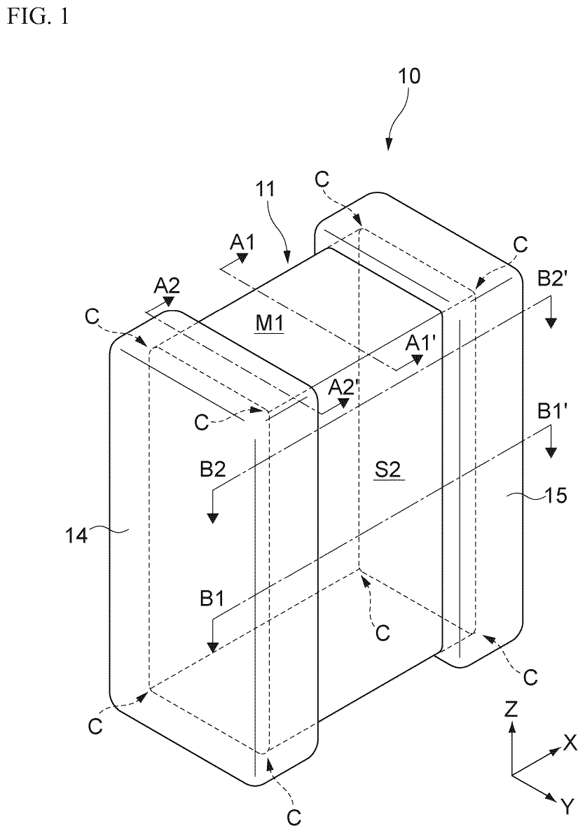

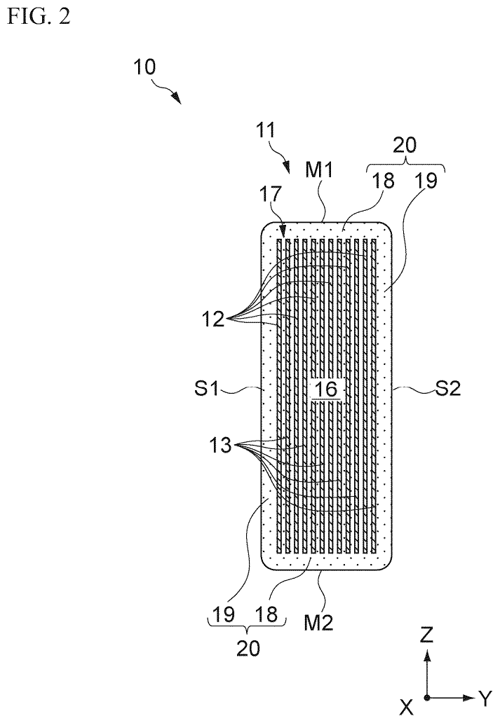

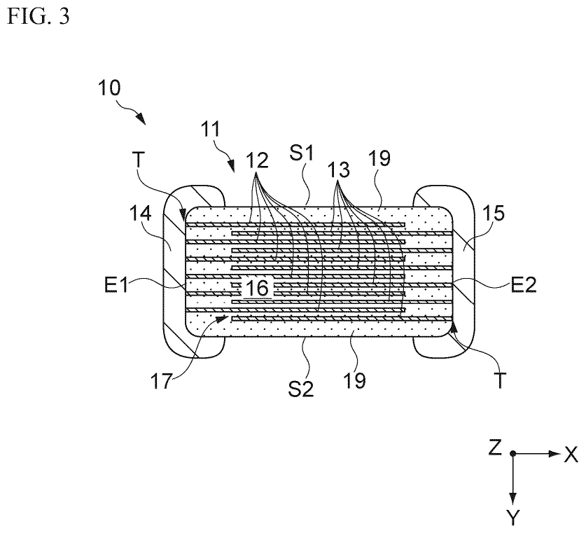

FIG. 1 to FIG. 3 illustrate the multilayer ceramic capacitor 10 according to a first embodiment of the present disclosure. FIG. 1 is a perspective view of the multilayer ceramic capacitor 10. FIG. 2 is a cross-sectional view of the multilayer ceramic capacitor 10 taken along line A1-A1′ in FIG. 1. FIG. 3 is a cross-sectional view of the multilayer ceramic capacitor 10 taken along line B1-B1′ in FIG. 1.

FIG. 2 and FIG. 3 illustrate cross sections of a section including the central portion of the multilayer ceramic capacitor 10. Specifically, FIG. 2 illustrates a vertical cross section along the Y-Z plane at the center in the X-axis direction of the multilayer ceramic capacitor 10. FIG. 3 illustrates a horizontal cross section along the X-Y plane at the center in the Z-axis direction of the multilayer ceramic capacitor 10.

The multilayer ceramic capacitor 10 includes a ceramic body 11, a first external electrode 14, and a second external electrode 15. The ceramic body 11 is configured as a hexahedron having first and second main surfaces M1 and M2 orthogonal to the Z-axis, first and second end surfaces E1 and E2 orthogonal to the X-axis, and a pair of side surfaces S1 and S2 orthogonal to the Y-axis.

The main surfaces M1 and M2, the end surfaces E1 and E2, and the side surfaces S1 and S2 of the ceramic body 11 are all flat surfaces. The flat surface in the present embodiment does not have to be strictly flat as long as it is a surface recognized as flat when viewed as a whole, and includes, for example, a surface having minute surface irregularities, a surface with a gently curved shape existing in a predetermined area, or the like.

The multilayer ceramic capacitor 10 is a tall type in which the dimension in the height direction along the Z-axis is equal to or greater than 1.5 times the dimension in the width direction along the Y-axis. In the multilayer ceramic capacitor 10, the capacitance is increased by increasing the dimension in the height direction. Thus, the multilayer ceramic capacitor 10 can be mounted in a mounting space limited in the width direction.

The multilayer ceramic capacitor 10 may be a tall type in which the dimension in the height direction along the Z-axis is equal to or greater than 1.3 times the dimension in the width direction along the Y-axis.

In the multilayer ceramic capacitor 10, the dimension in the length direction along the X-axis may be larger or smaller than the dimension in the height direction as long as it is larger than the dimension in the width direction. In the multilayer ceramic capacitor 10, the dimensions in the X-axis direction, the Y-axis direction, and the Z-axis direction can be freely determined within respective ranges satisfying the above conditions.

Specifically, in the multilayer ceramic capacitor 10, for example, the dimension in the length direction along the X-axis can be 0.2 mm or greater and 1.2 mm or less, the dimension in the width direction along the Y-axis can be 0.1 mm or greater and 0.7 mm or less, and the dimension in the height direction along the Z-axis can be 0.15 mm or greater and 1.0 mm or less.

The first external electrode 14 extends inward in the X-axis direction from the end surface E1 of the ceramic body 11 along the main surfaces M1 and M2 and the side surfaces S1 and S2, and the second external electrode 15 extends inward in the X-axis direction from the end surface E2 of the ceramic body 11 along the main surfaces M1 and M2 and the side surfaces S1 and S2. The first and second external electrodes 14 and 15 are separated from each other on the main surfaces M1 and M2 and the side surfaces S1 and S2. As a result, in both external electrodes 14 and 15, the cross sections along the X-Y and X-Z planes are U-shaped.

The ceramic body 11 is formed of a dielectric ceramic and has a structure in which a plurality of ceramic layers 17 each having a flat plate shape and extending along the X-Z plane are stacked in the Y-axis direction. The ceramic body 11 includes an electrode stacking portion 16 and a protective portion 20. The protective portion 20 covers the electrode stacking portion 16 from the Y-axis and Z-axis directions.

The electrode stacking portion 16 includes a plurality of sheet-shaped first and second internal electrodes 12 and 13 that are disposed between the ceramic layers 17 and extend along the X-Z plane. The internal electrodes 12 and 13 are alternately arranged along the Y-axis direction, and face each other in the Y-axis direction in the opposing section that is located in the center in the X-axis and Z-axis directions.

The first internal electrodes 12 are led out from the opposing section to respective connection ends T on the first end surface E1 and are connected to the first external electrode 14 at the respective connection ends T. The second internal electrodes 13 are led out from the opposing section to respective connection ends T on the second end surface E2 and are connected to the second external electrode 15 at the respective connection ends T on the second end surface E2.

With such a configuration, in the multilayer ceramic capacitor 10, when a voltage is applied between the external electrodes 14 and 15, the voltage is applied to the ceramic layers 17 between the internal electrodes 12 and 13 in the opposing section. As a result, in the multilayer ceramic capacitor 10, electric charge corresponding to the voltage between the external electrodes 14 and 15 is stored.

The protective portion 20 includes a pair of main-surface margin portions 18 that cover the electrode stacking portion 16 from respective sides in the Z-axis direction, and a pair of side-surface margin portions 19 that cover the electrode stacking portion 16 from respective sides in the Y-axis direction. The pair of main-surface margin portions 18 form the main surfaces M1 and M2 of the ceramic body 11. The pair of side-surface margin portions 19 form the side surfaces S1 and S2 of the ceramic body 11.

In the ceramic body 11, a dielectric ceramic having a high dielectric constant is used to increase the capacitance of each ceramic layer 17 between the internal electrodes 12 and 13. Examples of the dielectric ceramic having a high dielectric constant include a material having a perovskite structure containing barium (Ba) and titanium (Ti), which is represented by barium titanate (BaTiO₃).

The dielectric ceramic may be a composition system such as strontium titanate (SrTiO₃), calcium titanate (CaTiO₃), magnesium titanate (MgTiO₃), calcium zirconate (CaZrO₃), calcium zirconate titanate (Ca(Zr,Ti)O₃), barium calcium zirconate titanate ((Ba,Ca)(Zr,Ti)O₃), barium zirconate (BaZrO₃), or titanium dioxide (TiO₂).

In the multilayer ceramic capacitor 10, both the first and second external electrodes 14 and 15 are formed of copper (Cu) as a main component, and both the first and second internal electrodes 12 and 13 are formed of nickel (Ni) as a main component. In the present embodiment, the main component refers to a component having the highest content ratio.

In the multilayer ceramic capacitor 10, the external electrodes 14 and 15 formed of Cu as a main component and the connection ends T of the internal electrodes 12 and 13 formed of Ni as a main component are connected to each other on the end surfaces E1 and E2 of the ceramic body 11, respectively. The external electrodes 14 and 15 are configured as fired films fired on the ceramic body 11.

In the multilayer ceramic capacitor 10, conductor layers covering the external electrodes 14 and 15 may be provided to improve solder wettability and moisture resistance. Examples of such a conductor layer include a conductive plating layer formed by wet plating. The conductive plating layer may have a single-layer structure or a multilayer structure.

When the external electrodes 14 and 15 are fired on the ceramic body 11, Cu contained in the external electrodes 14 and 15 diffuses into the internal electrodes 12 and 13 from the connection ends T while reacting with Ni constituting the internal electrodes 12 and 13. That is, in the internal electrodes 12 and 13, Ni constituting the end portion in the X-axis direction including the connection end T reacts with Cu to form a copper-nickel alloy.

Particularly, when a metal having a lower melting point than Ni, which is the main component of the internal electrodes 12 and 13, and Cu, which is the main component of the external electrodes 14 and 15, is added to the internal electrodes 12 and 13 to improve the insulation properties, the diffusion of Cu from the external electrodes 14 and 15 to the internal electrodes 12 and 13 is further promoted. Examples of such a metal include zinc (Zn), tin (Sn), aluminum (Al), gallium (Ga), germanium (Ge), and silver (Ag).

In the internal electrodes 12 and 13, the end portions in the X-axis direction including the connection ends T expand in the thickness direction along the Y-axis due to the diffusion of Cu. Therefore, in the ceramic body 11, respective end portions in the X-axis direction of the internal electrodes 12 and 13, where the internal electrodes 12 and 13 expand, tend to expand in the stacking direction along the Y-axis, and thus internal stress is generated.

In general, in the ceramic body 11, internal stress caused by expansion of both end portions in the X-axis direction tends to concentrate on corner portions C. Here, the corner portions C of the ceramic body 11 refer to eight portions that connect three surfaces, that is, one of the main surfaces M1 and M2, one of the end surfaces E1 and E2, and one of the side surfaces S1 and S2 to each other, as illustrated in FIG. 1.

In the ceramic body 11, as the number of stacked internal electrodes 12 and 13 increases, the force of expansion generated by the expansion of each of the internal electrodes 12 and 13 is amplified, and thus the internal stress concentrated on the corner portion C increases. In the ceramic body 11, as the internal stress concentrated on the corner portion C increases, a crack is more likely to be generated in the corner portion C.

In the multilayer ceramic capacitor 10, when a crack is generated in the corner portion C of the ceramic body 11, the crack serves as a path through which moisture enters, and thus the moisture resistance is likely to be reduced. In addition, in the ceramic body 11, the corner portions C are covered with the external electrodes 14 and 15, and thus it is difficult to find a crack generated in the corner portion C by visual inspection.

In this regard, in the multilayer ceramic capacitor 10 according to the present embodiment, the stacking direction of the internal electrodes 12 and 13 in the ceramic body 11 is the Y-axis direction having a smaller dimension. Thus, in the multilayer ceramic capacitor 10, the number of stacked internal electrodes 12 and 13 in the ceramic body 11 can be kept small even in a tall structure.

Therefore, in the ceramic body 11, the amount of expansion of the internal electrodes 12 and 13 in the Y-axis direction due to diffusion of Cu contained in the external electrodes 14 and 15 can be reduced as a whole. Therefore, in the ceramic body 11, the internal stress caused by the expansion of the internal electrodes 12 and 13 can be kept small, and thus the generation of cracks can be inhibited.

In the ceramic body 11, the internal electrodes 12 and 13 are extended in the Z-axis direction in which the internal electrodes 12 and 13 have a large dimension, and thus the area of the section in which the internal electrodes 12 and 13 face each other can be increased. Therefore, in the multilayer ceramic capacitor 10, it is possible to increase the capacitance while keeping the number of stacked internal electrodes 12 and 13 in the ceramic body 11 small.

Furthermore, in the multilayer ceramic capacitor 10, by increasing the dimensions of the internal electrodes 12 and 13 in the Z-axis direction, a large connection area to the external electrode 14 at the connection end T of each of the internal electrodes 12 and a large connection area to the external electrode 15 at the connection end T of each of the internal electrodes 13 can be secured. Thus, in the multilayer ceramic capacitor 10, poor connection of each of the internal electrodes 12 to the external electrode 14 and poor connection of each of the internal electrodes 13 to the external electrode 15 are reduced or prevented.

In the multilayer ceramic capacitor 10 according to the present embodiment, the internal electrodes 12 and 13 are configured to be able to more effectively reduce the concentration of internal stress on the corner portions C of the ceramic body 11 due to the diffusion of Cu contained in the external electrodes 14 and 15 into the internal electrodes 12 and 13. The internal electrodes 12 and 13 will be described in detail below.

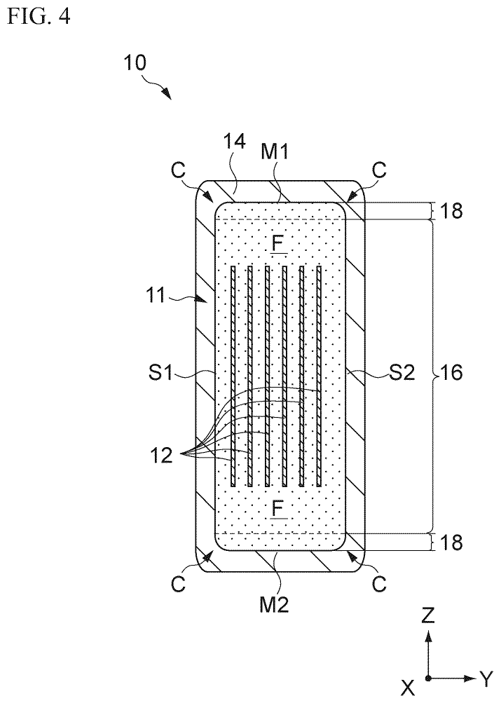

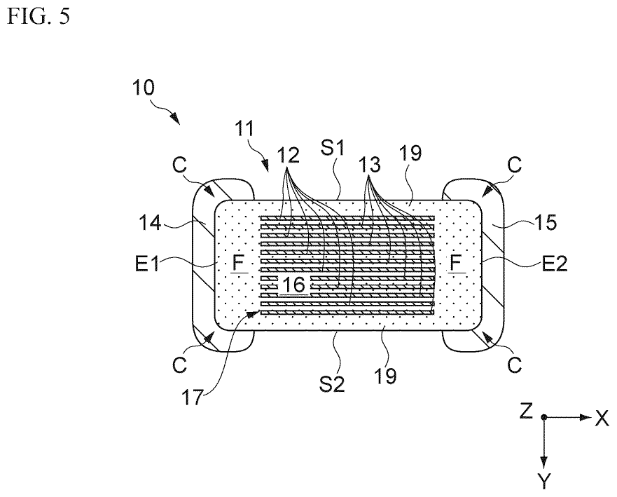

FIG. 4 is a vertical cross-sectional view of the multilayer ceramic capacitor 10 taken along line A2-A2′ in FIG. 1. FIG. 5 is a cross-sectional view of the multilayer ceramic capacitor 10 taken along line B2-B2′ in FIG. 1. FIG. 4 and FIG. 5 each illustrates a cross section of a section including the vicinities of the corner portions C of the ceramic body 11 in the multilayer ceramic capacitor 10.

Each of the internal electrodes 12 and 13 has absence sections F where no electrode material is arranged, in respective regions including the vicinities of eight corner portions C of the ceramic body 11, which are end portions in the X-axis, Y-axis, and Z-axis directions in the electrode stacking portion 16. That is, the internal electrodes 12 and 13 are disposed away from the corner portions C by being disposed so as to avoid the sections in the vicinities of the corner portions C.

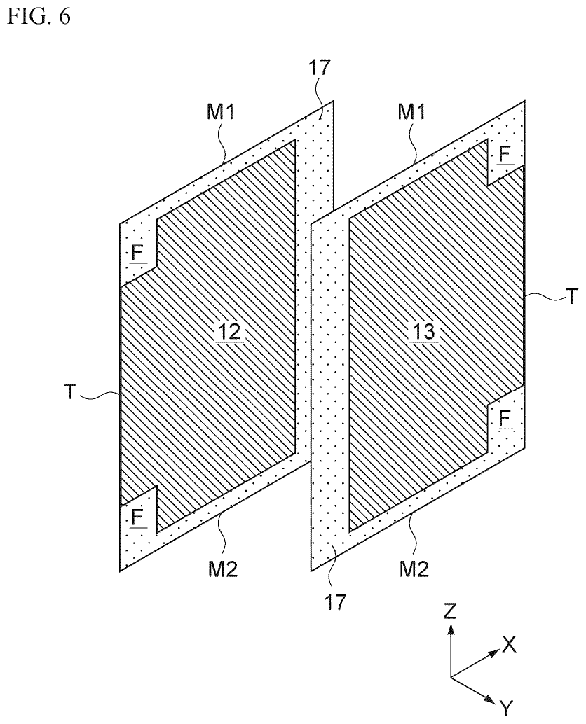

FIG. 6 illustrates the ceramic layers 17, one of which has the internal electrode 12 formed thereon, one of which has the internal electrode 13 formed thereon. As illustrated in FIG. 6, the internal electrodes 12 and 13 have a common planar shape with each other. That is, the internal electrodes 12 and 13 have a positional relationship in which the positions thereof are mutually horizontally reversed with respect to a central axis that is parallel to the Z-axis and passes through the center of the ceramic layer 17 in the X-axis direction.

As illustrated in FIG. 6, each of the internal electrodes 12 and 13 has the absence sections F formed in a rectangular cutout shape in both sides in the Z-axis direction in the end portion in the X-axis direction including the connection end T. Thus, each of the internal electrodes 12 and 13 has a planar shape that is narrowed inward from both sides in the Z-axis direction in the end portion in the X-axis direction including the connection end T.

In the internal electrodes 12 and 13, the respective distances from the main surfaces M1 and M2 are larger in the end portion in the X-axis direction including the connection end T than in the central portion in the X-axis direction. In the ceramic body 11, the absence sections F are provided in all the internal electrodes 12 and 13, and thus neither the internal electrode 12 nor 13 is present near the four ridge portions along the Y-axis direction.

Thus, in the ceramic body 11, the corner portions C are less likely to be affected by the expansion of the internal electrodes 12 and 13. In the ceramic body 11, internal stress caused by expansion of the internal electrodes 12 and 13 is reduced in the vicinities of the four ridge portions. Accordingly, in the ceramic body 11, the generation of cracks in the corner portions C can be effectively inhibited.

In the internal electrodes 12 and 13, as the dimension in the Z-axis direction of the absence section F increases, the respective distances from the main surfaces M1 and M2 of the ceramic body 11 increase. Therefore, the generation of cracks in the ceramic body 11 can be more effectively inhibited. Therefore, from this viewpoint, the dimension in the Z-axis direction of the absence section is preferably large.

On the other hand, in the internal electrodes 12 and 13, as the dimension in the Z-axis direction of the absence section F decreases, the respective connection areas to the external electrodes 14 and 15 at the connection ends T increase, and thus, poor connection to the external electrodes 14 and 15 can be more effectively inhibited. Therefore, from this viewpoint, a too large dimension in the Z-axis direction of the absence section F is not preferable.

Therefore, specifically, in the internal electrodes 12 and 13, the dimension in the Z-axis direction of the connection end T is preferably equal to or less than ⅘ of, more preferably equal to or less than ¾ of the dimension in the Z-axis direction of the central portion in the X-axis direction. In the internal electrodes 12 and 13, the dimension in the Z-axis direction of the connection end T is preferably equal to or greater than ½ of, more preferably equal to or greater than ⅔ of the dimension in the Z-axis direction of the central portion in the X-axis direction.

As illustrated in FIG. 5, the absence sections F of the internal electrode 12 preferably extend to positions inwardly beyond the portions of the external electrode 14 extending to the main surfaces M1 and M2 in the X-axis direction, and the absence sections F of the internal electrode 13 preferably extend to positions inwardly beyond the portions of the external electrode 15 extending to the main surfaces M1 and M2 in the X-axis direction. This can inhibit the generation of cracks in the portions of the ceramic body 11 covered with the external electrodes 14 and 15, which are difficult to visually inspect.

### Method of Manufacturing Multilayer Ceramic Capacitor 10

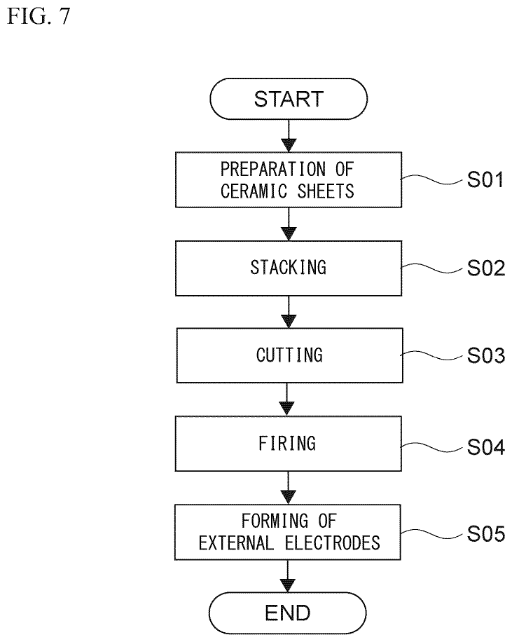

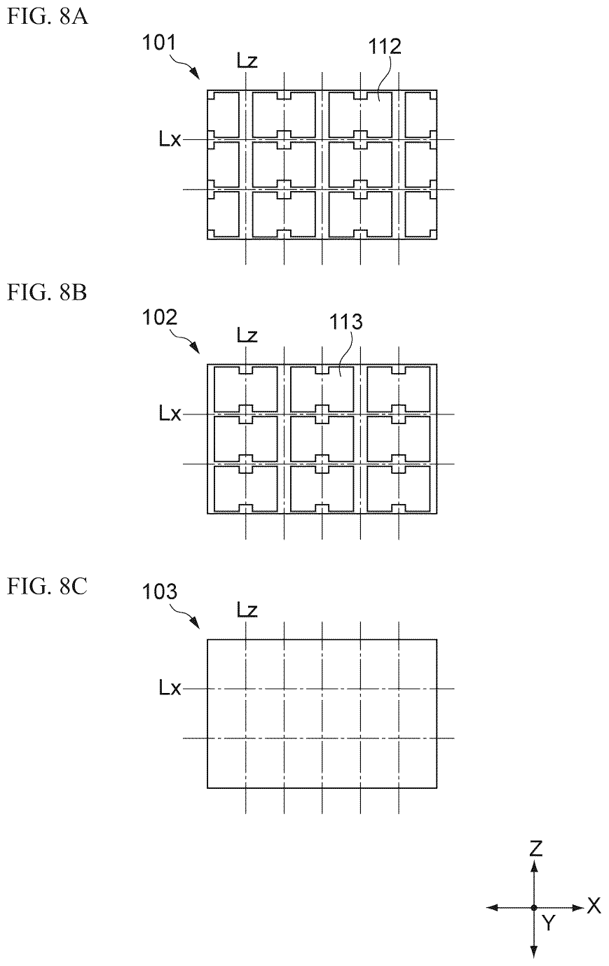

FIG. 7 is a flowchart illustrating a method of manufacturing the multilayer ceramic capacitor 10 according to the present embodiment. FIG. 8A to FIG. 10 illustrate a manufacturing process of the multilayer ceramic capacitor 10. Hereinafter, a method of manufacturing the multilayer ceramic capacitor 10 will be described along FIG. 7 with reference to FIG. 8A to FIG. 10 as appropriate.

### Step S01: Preparation of Ceramic Sheets

In step S01, first and second ceramic sheets 101 and 102 for forming the electrode stacking portion 16 and the main-surface margin portions 18, and third ceramic sheets 103 for forming the side-surface margin portions 19 are prepared. FIG. 8A, FIG. 8B, and FIG. 8C are plan views of the ceramic sheets 101, 102, and 103, respectively.

The ceramic sheets 101, 102, and 103 prepared in step S01 are each formed as an unfired dielectric green sheet containing a dielectric ceramic as a main component. The ceramic sheets 101, 102, and 103 are formed into a sheet shape by using, for example, a roll coater or a doctor blade.

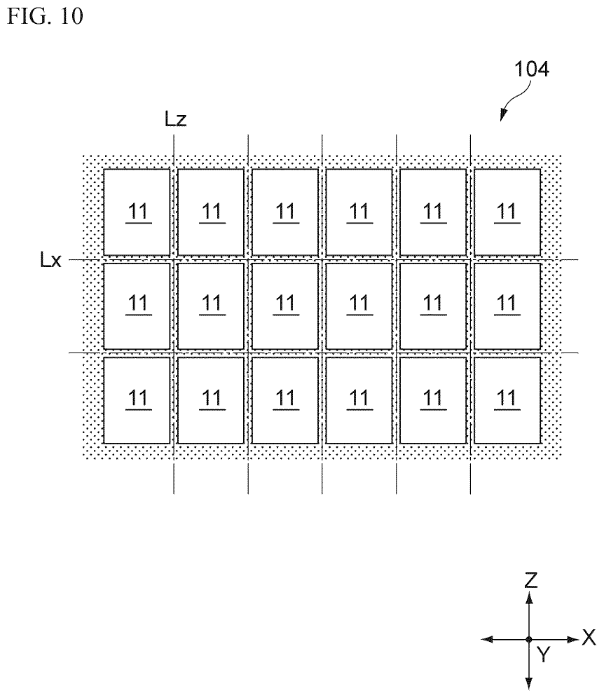

In this stage, each of the ceramic sheets 101, 102, and 103 is configured as a large-sized sheet that is not separated into individual pieces. In FIG. 8A, FIG. 8B, FIG. 8C, and FIG. 10, first cut lines Lx parallel to the X-axis and second cut lines Lz parallel to the Z-axis are indicated by dash-dotted lines as cut lines for separating the multilayer ceramic capacitors 10 into individual pieces.

Unfired conductor patterns 112 and 113 corresponding to the internal electrodes 12 and 13 are formed on the ceramic sheets 101 and 102 constituting the electrode stacking portion 16 and the main-surface margin portions 18, respectively. On the other hand, no conductor pattern is formed on the third ceramic sheets 103 corresponding to the side-surface margin portions 19 where no internal electrodes are provided.

The conductor patterns 112 and 113 are formed by applying a conductive paste containing Ni as a main component to the ceramic sheets 101 and 102, respectively. The method of applying the conductive paste can be freely selected from known techniques, and for example, a screen printing method or a gravure printing method can be used.

In each of the conductor patterns 112 and 113, spaces that have widths in the Z-axis direction and are along the cut lines Lx are formed for every cut line Lx, and spaces that have widths in the X-axis direction and are along the cut lines Lz are formed with one cut line Lz1 interposed therebetween. The spaces along the cut lines Lz of the conductor pattern 112 and the spaces along the cut lines Lz of the conductor pattern 113 are alternately arranged along the X-axis direction.

### Step S02: Stacking

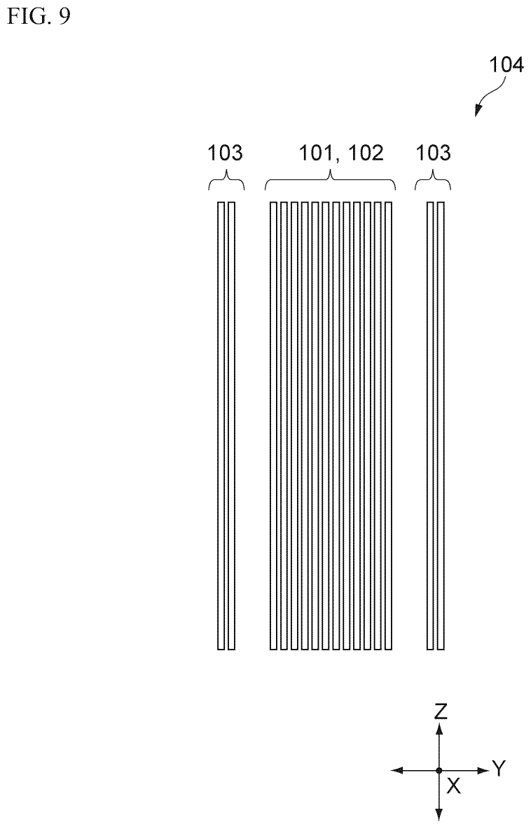

In step S02, the ceramic sheets 101, 102, and 103 prepared in step S01 are stacked as illustrated in FIG. 9 to produce a multilayer sheet 104. The multilayer sheet 104 is obtained by integrating the stacked ceramic sheets 101, 102, and 103 by hydrostatic pressurization, uniaxial pressurization, or the like.

In the multilayer sheet 104, the ceramic sheets 101 and 102 are alternately stacked in the Y-axis direction at positions corresponding to the electrode stacking portion 16 and the main-surface margin portions 18. In the multilayer sheet 104, the third ceramic sheets 103 corresponding to the side-surface margin portions 19 are stacked on both sides in the Y-axis direction of the stacked ceramic sheets 101 and 102.

### Step S03: Cutting

In step S03, the multilayer sheet 104 obtained in step S02 is cut along the cut lines Lx and Lz as illustrated in FIG. 10, and thus the unfired ceramic bodies 11 are obtained. For example, a cutting device provided with a push-cutting blade or a dicing device provided with a rotary blade can be used to cut the multilayer sheet 104 in step S03.

### Step S04: Firing

In step S04, the ceramic body 11 obtained in step S03 is fired. The firing temperature in step S04 can be set to about 1000 to 1300° C., for example, when a barium titanate (BaTiO₃)-based material is used. The firing can be performed, for example, in a reducing atmosphere or a low oxygen partial pressure atmosphere.

### Step S05: Forming of External Electrodes

In step S05, the multilayer ceramic capacitor 10 illustrated in FIG. 1 to FIG. 3 is produced by forming the external electrodes 14 and 15 on respective end portions in the X-axis direction of the ceramic body 11 obtained in step S04. The external electrodes 14 and 15 are formed by applying a conductive paste containing Cu as a main component to the ceramic body 11 and firing the conductive paste.

In step S05, Cu in the conductive paste diffuses into the internal electrodes 12 and 13 while reacting with Ni constituting the internal electrodes 12 and 13. However, as described above, in the ceramic body 11, even when the internal electrodes 12 and 13 expand due to the diffusion of Cu, the generation of cracks is inhibited by the above-described effect.

### Mounting of Multilayer Ceramic Capacitor 10

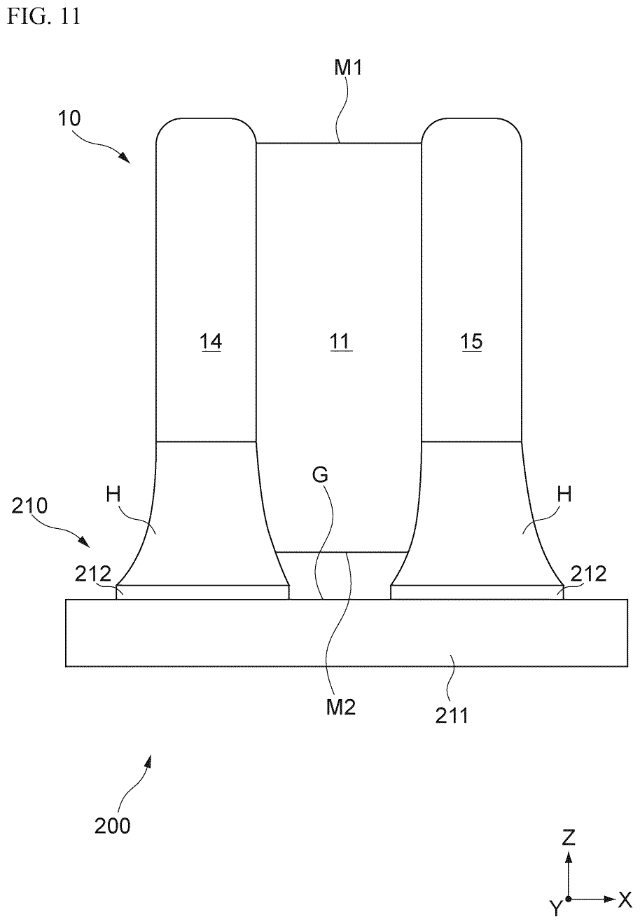

FIG. 11 is a side view of a circuit board 200 including the multilayer ceramic capacitor 10 according to the present embodiment. The circuit board 200 includes a mounting substrate 210 on which the multilayer ceramic capacitor 10 is mounted. The mounting substrate 210 includes a base material 211 that extends along the X-Y plane and has a mounting surface G perpendicular to the Z-axis, and a pair of connection electrodes 212 provided on the mounting surface G.

In the circuit board 200, the external electrodes 14 and 15 of the multilayer ceramic capacitor 10 are connected to the pair of connection electrodes 212 of the mounting substrate 210, respectively, with the solder H interposed therebetween. Accordingly, in the circuit board 200, the multilayer ceramic capacitor 10 is fixed to and electrically connected to the mounting substrate 210.

Here, in the multilayer ceramic capacitor 10, it is known that when a voltage is applied to the external electrodes 14 and 15 through the connection electrodes 212 of the mounting substrate 210 at the time of driving the circuit board 200, electrostriction occurs in the ceramic body 11 due to the piezoelectric effect. The electrostriction generated in the ceramic body 11 causes relatively large deformation in the stacking direction of the internal electrodes 12 and 13.

In the circuit board 200, repeated electrostriction in the multilayer ceramic capacitor 10 to which an AC voltage is applied may cause vibration in the thickness direction in the base material 211 of the mounting substrate 210. In the circuit board 200, when the vibration generated in the base material 211 increases, a phenomenon called “sound emission” in which noise sound is emitted from the base material 211 may occur.

In this regard, in the multilayer ceramic capacitor 10 according to the present embodiment, the stacking direction of the internal electrodes 12 and 13 is the in-plane direction of the base material 211, and thus vibration in the thickness direction is less likely to be generated in the base material 211 due to the electrostriction of the ceramic body 11. In the multilayer ceramic capacitor 10, the number of stacked internal electrodes 12 and 13 is small, and the amount of deformation due to electrostriction is thereby kept small. Therefore, even when vibration is generated in the base material 211, the vibration is unlikely to be so large as to cause noise.

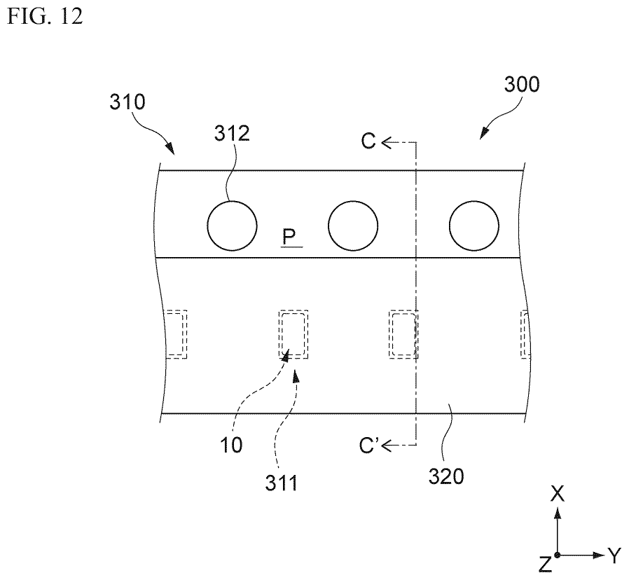

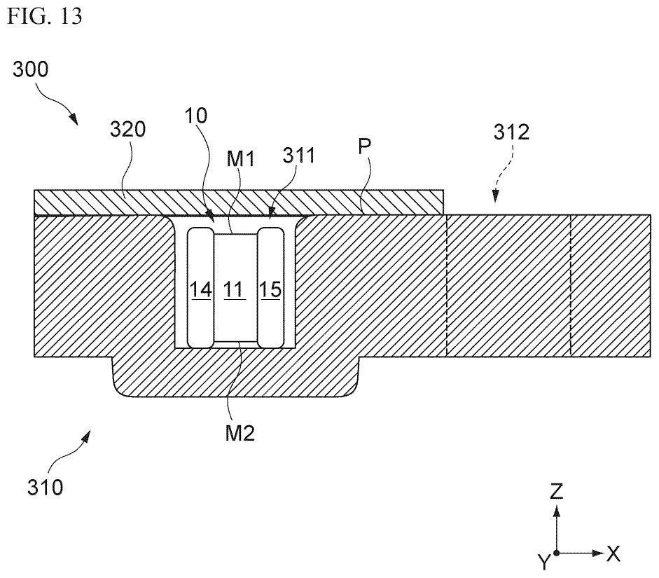

The multilayer ceramic capacitor 10 is prepared in a state of being packaged as a package 300 when being mounted on the mounting substrate 210. FIG. 12 and FIG. 13 illustrate the package 300. FIG. 12 is a partial plan view of the package 300. FIG. 13 is a cross-sectional view of the package 300 taken along line C-C′ in FIG. 12.

The package 300 includes the multilayer ceramic capacitor 10, a carrier tape 310, and a top tape 320. The carrier tape 310 is configured as a long tape extending in the Y-axis direction. In the carrier tape 310, a plurality of recesses 311 each accommodating one multilayer ceramic capacitor 10 are arranged at intervals in the Y-axis direction.

The carrier tape 310 has a sealing surface P that is an upward surface orthogonal to the Z-axis, and the plurality of recesses 311 are recessed downward in the Z-axis direction from the sealing surface P. That is, the carrier tape 310 is configured so that the multilayer ceramic capacitors 10 in the plurality of recesses 311 can be taken out from the sealing surface P side.

In the carrier tape 310, a plurality of feed holes 312 penetrating through the carrier tape 310 in the Z-axis direction and arranged at intervals in the Y-axis direction are provided at positions shifted in the X-axis direction from the row of the plurality of recesses 311. The feed holes 312 are configured as engagement holes used for the tape transport mechanism to transport the carrier tape 310 in the Y-axis direction.

In the package 300, the top tape 320 is attached to the sealing surface P of the carrier tape 310 along the row of the recesses 311, and the plurality of recesses 311 accommodating the multilayer ceramic capacitors 10, respectively, are collectively covered with the top tape 320. Thus, the multilayer ceramic capacitors 10 are held in the recesses 311, respectively.

As illustrated in FIG. 13, in the multilayer ceramic capacitor 10 in the recess 311 of the carrier tape 310, the first main surface M1 of the ceramic body 11 facing upward in the Z-axis direction faces the top tape 320. The second main surface M2 of the ceramic body 11 facing downward in the Z-axis direction faces the bottom surface of the recess 311.

When the multilayer ceramic capacitor 10 packaged as the package 300 is mounted, the top tape 320 is peeled off from the sealing surface P of the carrier tape 310 along the Y-axis direction. This allows the recesses 311 in which the multilayer ceramic capacitors 10 are accommodated, respectively, to be sequentially opened upward in the Z-axis direction in the package 300.

The multilayer ceramic capacitor 10 accommodated in the opened recess 311 is taken out in a state where the first main surface M1 of the ceramic body 11 facing upward in the Z-axis direction is sucked by the tip of a suction nozzle of a mounting device. The mounting device moves the suction nozzle to move the multilayer ceramic capacitor 10 onto the mounting surface G of the mounting substrate 210.

Then, the mounting device causes the second main surface M2 of the ceramic body 11 to face the mounting surface G, and releases the suction of the first main surface M1 of the ceramic body 11 by the suction nozzle in a state where the external electrodes 14 and 15 are aligned on the pair of connection electrodes 212 to which the solder paste is applied. Thus, the multilayer ceramic capacitor 10 is mounted on the mounting surface G.

Then, the solder paste is melted and then hardened by putting the mounting substrate 210 with the mounting surface G on which the multilayer ceramic capacitor 10 is placed in a reflow furnace or the like. Thus, the external electrodes 14 and 15 of the multilayer ceramic capacitor 10 are connected to the pair of connection electrodes 212 of the mounting substrate 210 through the solder H, whereby the circuit board 200 illustrated in FIG. 11 is obtained.

### Second Embodiment

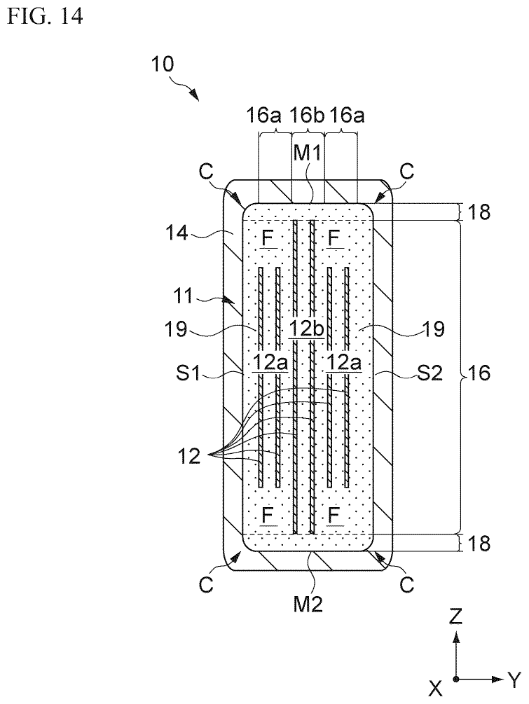

The multilayer ceramic capacitor 10 according to a second embodiment of the present disclosure is different from the multilayer ceramic capacitor 10 according to the first embodiment only in the configuration of the internal electrodes 12 and 13, and has the appearance illustrated in FIG. 1, similarly to the multilayer ceramic capacitor 10 according to the first embodiment. FIG. 14 to FIG. 16 illustrate the multilayer ceramic capacitor 10 according to the second embodiment.

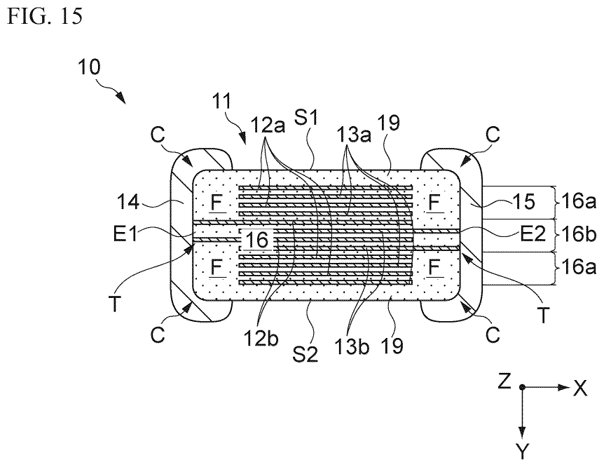

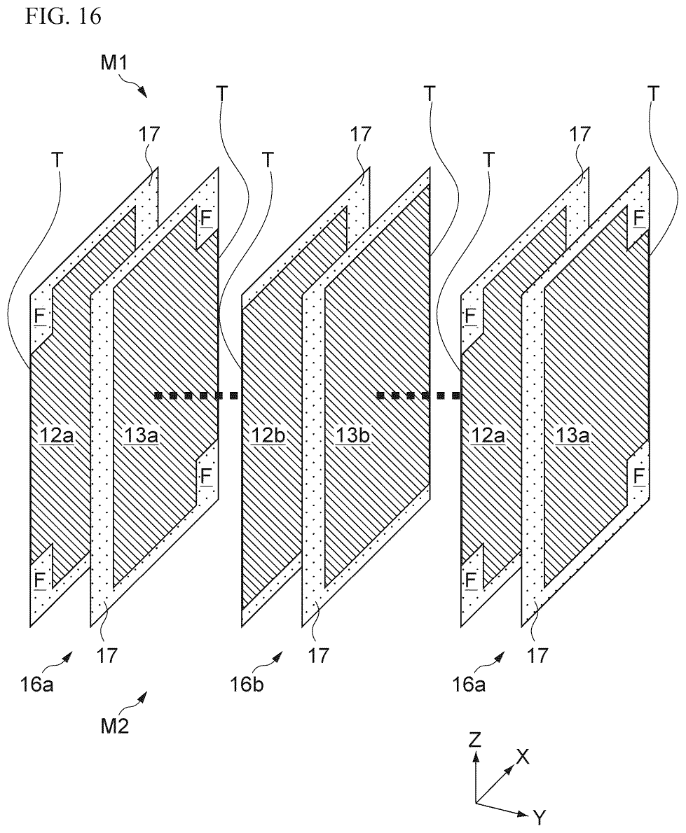

FIG. 14 is a vertical cross-sectional view of the multilayer ceramic capacitor 10 taken along line A2-A2′ in FIG. 1. FIG. 15 is a horizontal cross-sectional view of the multilayer ceramic capacitor 10 taken along line B2-B2′ in FIG. 1. FIG. 16 is a partially exploded view illustrating the ceramic layers 17 of the ceramic body 11 of the multilayer ceramic capacitor 10.

In FIG. 14 and FIG. 15, the electrode stacking portion 16 is divided along the Y-axis direction into a pair of outer-side portions 16a, which are located in respective outer sides in the Y-axis direction, and an inner-side portion 16b, which is located in the inner side in the Y-axis direction. That is, in the electrode stacking portion 16, the pair of outer-side portions 16a are adjacent to the pair of side-surface margin portions 19, and the inner-side portion 16b is located between the pair of outer-side portions 16a.

As described above, in the multilayer ceramic capacitor 10 according to the first embodiment, the internal electrodes 12 and 13 have the same shape. In contrast, in the multilayer ceramic capacitor 10 according to the present embodiment, the shapes of the internal electrodes 12 and 13 are different between the outer-side portion 16a and the inner-side portion 16b, and the absence sections F are provided only in the internal electrodes 12 and 13 located in the outer-side portion 16a.

More specifically, the first and second internal electrodes 12 and 13 include first and second outer-side internal electrodes 12a and 13a stacked in each of the pair of outer-side portions 16a, and first and second inner-side internal electrodes 12b and 13b stacked in the inner-side portion 16b. In the internal electrodes 12 and 13, the outer-side internal electrodes 12a and 13a have shapes different from those of the inner-side internal electrodes 12b and 13b.

The outer-side internal electrodes 12a and 13a have the same shape as the internal electrodes 12 and 13 of the first embodiment. In contrast, the inner-side internal electrodes 12b and 13b do not have a planar shape narrowed in the end portion in the X-axis direction including the connection end T, and the dimension in the Z-axis direction is as large as that in the central portion in the X-axis direction throughout the X-axis direction.

Thus, the absence sections F are formed in each of the outer-side internal electrodes 12a and 13a, and no absence section F is formed in the inner-side internal electrodes 12b and 13b. In the multilayer ceramic capacitor 10 according to the present embodiment, the absence sections F are provided only in the pair of outer-side portions 16a, and thus it is possible to reliably inhibit the internal stress from concentrating on the corner portions C of the ceramic body 11.

In the inner-side internal electrodes 12b and 13b disposed in the central portion in the Y-axis direction where internal stress is less likely to concentrate, the connection areas of the connection ends T to the external electrodes 14 and 15 can be increased by ensuring a large dimension in the Z-axis direction of the connection ends T. This can reduce or inhibit poor connection between the internal electrodes 12 and the external electrode 14 and poor connection between the internal electrodes 13 and the external electrode 15.

In the internal electrodes 12 and 13, the absence section F becomes larger as the ratio of the total number of stacked outer-side internal electrodes 12a and 13a in the pair of outer-side portions 16a to the total number of stacked internal electrodes 12 and 13 increases, and thus, the generation of cracks in the ceramic body 11 can be more effectively inhibited. Therefore, from this viewpoint, the number of stacked outer-side internal electrodes 12a and 13a is preferably large.

On the other hand, in the internal electrodes 12 and 13, as the ratio of the number of stacked inner-side internal electrodes 12b and 13b to the total number of stacked internal electrodes 12 and 13 increases, poor connection between the internal electrodes 12 and the external electrode 14 and poor connection between the internal electrodes 13 and the external electrode 15 can be more effectively inhibited. Therefore, from this viewpoint, the too large number of stacked outer-side internal electrodes 12a and 13a is not preferable.

Therefore, the number of stacked outer-side internal electrodes 12a and 13a is preferably equal to or greater than 10% of, more preferably equal to or greater than 25% of the total number of stacked internal electrodes 12 and 13. The number of stacked outer-side internal electrodes 12a and 13a is preferably equal to or less than 50% of, more preferably equal to or less than 40% of the total number of stacked internal electrodes 12 and 13.

### Third Embodiment

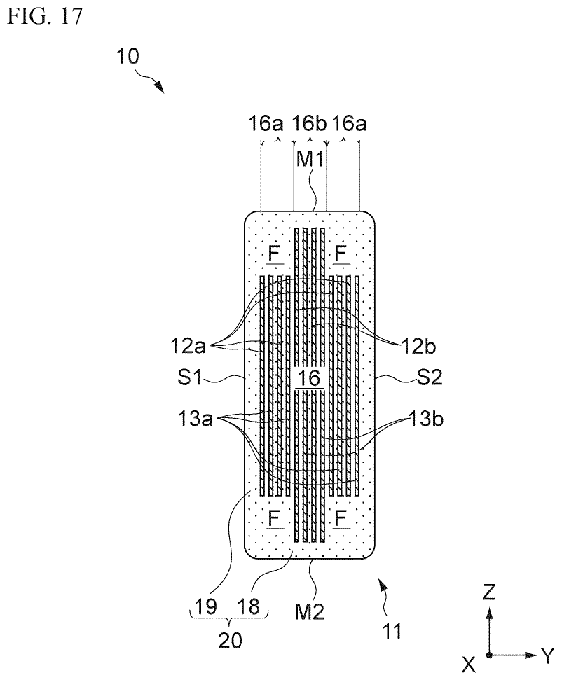

The multilayer ceramic capacitor 10 according to a third embodiment is different from the multilayer ceramic capacitor 10 according to the second embodiment only in the configuration of the internal electrodes 12 and 13, and has the appearance illustrated in FIG. 1, similarly to the multilayer ceramic capacitor 10 according to the second embodiment. FIG. 17 to FIG. 19 illustrate the multilayer ceramic capacitor 10 according to the third embodiment.

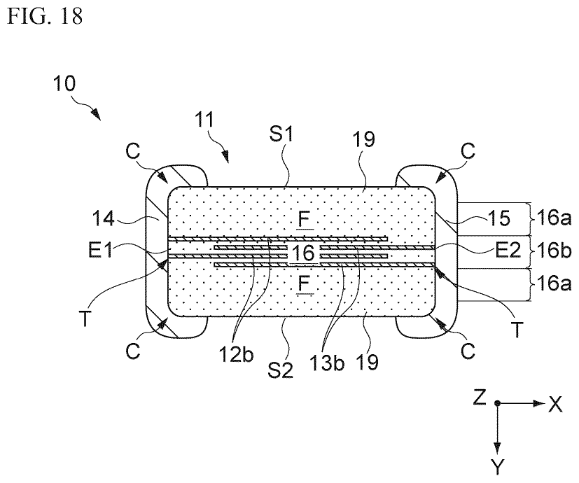

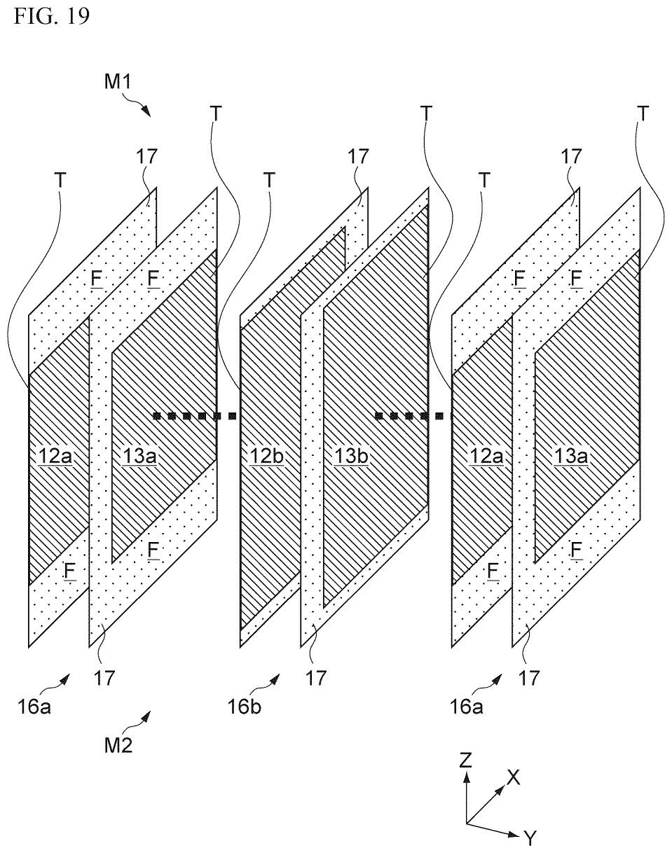

FIG. 17 is a vertical cross-sectional view of the multilayer ceramic capacitor 10 taken along line A1-A1′ in FIG. 1. FIG. 18 is a horizontal cross-sectional view of the multilayer ceramic capacitor 10 taken along line B2-B2′ in FIG. 1. FIG. 19 is a partial exploded view illustrating the ceramic layers 17 of the ceramic body 11 of the multilayer ceramic capacitor 10.

The inner-side internal electrodes 12b and 13b have the same shape as the inner-side internal electrodes 12b and 13b of the second embodiment. In contrast, the outer-side internal electrodes 12a and 13a do not have a planar shape narrowed in the end portion in the X-axis direction including the connection end T, and the dimension in the Z-axis direction is smaller than those of the inner-side internal electrodes 12b and 13b throughout the X-axis direction.

That is, the band-shaped absence sections F extending throughout the X-axis direction are formed at both end portions in the Z-axis direction of the inner-side internal electrodes 12b and 13b. Accordingly, in the multilayer ceramic capacitor 10 according to the present embodiment, the generation of cracks due to the concentration of internal stress is significantly inhibited in the entirety of the four ridge portions along the X-axis direction of the ceramic body 11.

### Examples

As Example 1 of the present disclosure, a sample of the multilayer ceramic capacitor 10 according to the first embodiment described above was fabricated. In addition, as Example 2 of the present disclosure, a sample of the multilayer ceramic capacitor 10 according to the second embodiment described above was fabricated. One hundred samples were prepared for each of Examples 1 and 2.

As Example 3 of the present disclosure, a sample of the multilayer ceramic capacitor 10 according to the first embodiment described above was fabricated. In addition, as Example 4 of the present disclosure, a sample of the multilayer ceramic capacitor 10 according to the second embodiment described above was fabricated. One hundred samples were prepared for each of Examples 3 and 4.

In all the samples of Examples 1 and 2, the dimension in the length direction along the X-axis was 600 μm, the dimension in the width direction along the Y-axis was 300 μm, and the dimension in the height direction along the Z-axis was 500 μm. In all the samples of Examples 1 and 2, the thickness of the protective portion 20 around the electrode stacking portion 16 was 25 μm.

In all the samples of Examples 3 and 4, the dimension in the length direction along the X-axis was 600 μm, the dimension in the width direction along the Y-axis was 300 μm, and the dimension in the height direction along the Z-axis was 400 μm. In all the samples of Examples 3 and 4, the thickness of the protective portion 20 around the electrode stacking portion 16 was 25 μm.

In the samples of Example 1, the dimension in the Z-axis direction of the central portion in the X-axis direction of each of the internal electrodes 12 and 13 was 450 μm. In the samples of Example 1, the dimension in the Z-axis direction of the portion narrowed in the Z-axis direction in the end portion in the X-axis direction including the connection end T of each of the internal electrodes 12 and 13 was 300 μm, and the dimension in the X-axis direction was 25 μm.

In the samples of Example 2, the shapes of the outer-side internal electrodes 12a and 13a were the same as those of the internal electrodes 12 and 13 of the samples of Example 1. In the samples of Example 2, the dimension in the Z-axis direction of the inner-side internal electrode was 450 μm. In each of Examples 1 and 2, the thickness of each of the internal electrodes 12 and 13 and the ceramic layers 17 was 0.5 μm.

In the samples of Example 3, the dimension in the Z-axis direction of the central portion in the X-axis direction of each of the internal electrodes 12 and 13 was 350 μm. In the samples of Example 3, the dimension in the Z-axis direction of the portion narrowed in the Z-axis direction in the end portion in the X-axis direction including the connection end T of each of the internal electrodes 12 and 13 was 300 μm, and the dimension in the X-axis direction was 25 μm.

In the samples of Example 4, the shapes of the outer-side internal electrodes 12a and 13a were the same as those of the internal electrodes 12 and 13 of the samples of Example 3. In the samples of Example 4, the dimension in the Z-axis direction of the inner-side internal electrode was 350 μm. In each of Examples 3 and 4, the thickness of each of the internal electrodes 12 and 13 and the ceramic layers 17 was 0.5 μm.

In all the samples of Examples 1 and 2, the total number of stacked internal electrodes 12 and 13 was 250. In the samples of Example 2, the number of stacked outer-side internal electrodes 12a and 13a in each of the pair of outer-side portions 16a was 50, and the number of stacked inner-side internal electrodes 12b and 13b in the inner-side portion 16b was 150.

In all the samples of Examples 3 and 4, the total number of stacked internal electrodes 12 and 13 was 250. In the samples of Example 4, the number of stacked outer-side internal electrodes 12a and 13a in each of the pair of outer-side portions 16a was 50, and the number of stacked inner-side internal electrodes 12b and 13b in the inner-side portion 16b was 150.

In addition, as Comparative Example 1 of the present disclosure, 100 samples having a general configuration in which the stacking direction of the first and second internal electrodes was the height direction were fabricated. In the samples of Comparative Example 1, the dimension in the length direction, the dimension in the width direction, the dimension in the height direction, the thickness of the protective portion, the thickness of each of the first and second internal electrodes, and the thickness of each of the ceramic layers were set to be equivalent to those of the samples of Examples 1 and 2.

In the samples of Comparative Example 1, the first and second internal electrodes were not formed in a shape narrowed in the end portion in the X-axis direction including the connection end, that is, no absence section is provided in the first and second internal electrodes. In the samples of Comparative Example 1, the dimension in the Y-axis direction of each of the first and second internal electrodes was 250 μm, and the total number of stacked first and second internal electrodes was 450.

As Comparative Example 2 of the present disclosure, 100 samples having a general configuration in which the stacking direction of the first and second internal electrodes was the height direction were prepared. In the samples of Comparative Example 2, the dimension in the length direction, the dimension in the width direction, the dimension in the height direction, the thickness of the protective portion, the thickness of each of the first and second internal electrodes, and the thickness of each of the ceramic layers were set to be equivalent to those of the samples of Examples 3 and 4.

In the samples of Comparative Example 2, the first and second internal electrodes were not formed in a shape narrowed in the end portion in the X-axis direction including the connection end, that is, no absence section was provided in the first and second internal electrodes. In the samples of Comparative Example 2, the dimension in the Y-axis direction of each of the first and second internal electrodes was 250 μm, and the total number of stacked first and second internal electrodes was 350.

The samples of Examples 1 and 2 were observed in cross section to check whether cracks were generated in the corner portions C of the ceramic body 11. In Examples 1 and 2, no crack was found in the corner portions C of the ceramic body 11 in all the samples, and it was confirmed that the effect of the present disclosure was obtained.

The samples of Examples 3 and 4 were observed in cross section to check whether cracks were generated in the corner portions C of the ceramic body 11. In Examples 3 and 4, no crack was found in the corner portions C of the ceramic body 11 in all the samples, and it was confirmed that the effect of the present disclosure was obtained.

The samples of Comparative Example 1 were also observed in cross section in the same manner to check whether cracks were generated in the corner portions C of the ceramic body. In all the samples of Comparative Example 1, the generation of cracks, which is considered to be caused by the expansion of the end portions in the X-axis direction including the connection ends of the first and second internal electrodes, was observed in one of the corner portions of the ceramic body.

The samples of Comparative Example 2 were also observed in cross section to check whether cracks were generated in the corner portions C of the ceramic body. In all the samples of Comparative Example 2, the generation of cracks, which is considered to be caused by the expansion of the end portions in the X-axis direction including the connection ends of the first and second internal electrodes, was observed in one of the corner portions of the ceramic body.

Next, the electrostatic capacitance was measured under the conditions of 1 kHz and 0.5 Vrms for 100 samples of each of Examples 1 and 2. The average value of the electrostatic capacitance was obtained for each of Examples 1 and 2, and samples of which the electrostatic capacitance was within a range of ±5% centered on the average value were determined to be acceptable. The samples of Examples 1 and 2 were all acceptable.

Next, the electrostatic capacitance was measured under the conditions of 1 kHz and 0.5 Vrms for 100 samples of each of Examples 3 and 4. The average value of the electrostatic capacitance was obtained for each of Examples 3 and 4, and samples of which the electrostatic capacitance was within a range of ±5% centered on the average value were determined to be acceptable. The samples of Examples 3 and 4 were all acceptable.

The same evaluation of electrostatic capacitance was performed on 100 samples of Comparative Example 1. Some samples of Comparative Example 1 were rejectable. That is, it was confirmed that a variation in capacitance was large in the samples of Comparative Example 1. It is considered that poor connection between the internal electrode and the external electrode occurred in the rejectable samples.

The same evaluation of the electrostatic capacitance was performed on 100 samples of Comparative Example 2. Some samples of Comparative Example 2 were rejectable. That is, it was confirmed that a variation in capacitance was large in the samples of Comparative Example 2. It is considered that the poor connection between the internal electrode and the external electrode occurred in the rejectable samples.

That is, in the samples of Examples 1 and 2, the dimension in the Z-axis direction of the connection end T of each of the internal electrodes 12 and 13 is 450 μm or 300 μm, and connection areas with the external electrodes 14 and 15 of at least 150 μm² (300 μm×0.5 μm) or greater can be secured at the respective connection ends T of the internal electrodes 12 and 13.

In the samples of Examples 3 and 4, the dimension in the Z-axis direction of the connection end T of each of the internal electrodes 12 and 13 is 400 μm or 300 μm, and connection areas with the external electrodes 14 and 15 of at least 150 μm² (300 μm×0.5 μm) or greater can be secured at the respective connection ends T of the internal electrodes 12 and 13.

On the other hand, in the samples of Comparative Example 1, the dimension in the Y-axis direction of the connection end of the internal electrode is 250 μm, and the connection area with the external electrode at the connection end of each internal electrode is only 125 μm² (250μm×0.5 μm). Therefore, it is considered that, in Comparative Example 1, samples including internal electrodes having poor connection to the external electrode were generated.

Also in the samples of Comparative Example 2, the dimension in the Y-axis direction of the connection end of the internal electrode is 250 μm, and the connection area with the external electrode at the connection end of each internal electrode is only 125 μm² (250 μm×0.5 μm). Therefore, it is considered that, also in Comparative Example 2, samples including internal electrodes having poor connection with the external electrode were generated. Other Embodiments

Although the embodiments of the present disclosure have been described above, the present invention is not limited to the above-described embodiments, and various modifications can be made.

For example, in the multilayer ceramic capacitor 10 according to the third embodiment, the configuration of the inner-side internal electrodes 12b and 13b may not be necessarily the same as those of the inner-side internal electrodes 12b and 13b of the second embodiment. For example, the configurations of the inner-side internal electrodes 12b and 13b according to the third embodiment may be similar to those of the internal electrodes 12 and 13 of the first embodiment.

The shape of the absence section F in each of the internal electrodes 12 and 13 can be changed within a range in which the effect of the present disclosure is exhibited. For example, the absence section F of each of the internal electrodes 12 and 13 may have an outline form including a curve. In the internal electrodes 12 and 13, the shape of the absence section F may be different between the first main surface M1 side and the second main surface M2 side.

Furthermore, in the multilayer ceramic capacitor 10, the first main surface M1 and the second main surface M2 of the ceramic body 11 may be reversed. That is, in the circuit board 200 illustrated in FIG. 11 and the multilayer ceramic capacitor 10 in the package 300 illustrated in FIG. 13, the first main surface M1 may face downward in the Z-axis direction and the second main surface M2 may face upward in the Z-axis direction.

What is claimed is:

1. A multilayer ceramic capacitor that has a dimension in a first direction along a first axis equal to or greater than 1.5 times a dimension in a second direction along a second axis orthogonal to the first axis, and is configured to be mounted on a mounting surface perpendicular to the first axis, the multilayer ceramic capacitor comprising:
a ceramic body having a pair of main surfaces perpendicular to the first axis, an end surface perpendicular to a third axis orthogonal to the first axis and the second axis, and a plurality of internal electrodes that contain Ni as a main component, are stacked in the second direction, and are led out to respective connection ends on the end surface; and
an external electrode that contains Cu as a main component and covers the end surface,
wherein the plurality of internal electrodes include outer-side internal electrodes located in both outer sides in the second direction and inner-side internal electrodes located in an inner side in the second direction, and
wherein respective distances from the pair of main surfaces at the connection end of each of the outer-side internal electrodes are larger than respective distances from the pair of main surfaces in a central portion in a third direction along the third axis of the inner-side internal electrode.

2. The multilayer ceramic capacitor according to claim 1, wherein each of the internal electrodes has larger distances from the pair of main surfaces at the connection end than in a central portion in the third direction thereof.

3. The multilayer ceramic capacitor according to claim 1, wherein the respective distances from the pair of main surfaces of each of the outer-side internal electrodes are larger than those in the central portion in the third direction of each of the inner-side internal electrodes throughout each of the outer-side internal electrodes in the third direction.

4. The multilayer ceramic capacitor according to claim 1, wherein the respective distances from the pair of main surfaces at the connection end of each of the outer-side internal electrodes are larger than respective distances from the pair of main surfaces at the connection end of each of the inner-side internal electrodes.

5. A package comprising:
the multilayer ceramic capacitor according to claim 1;
a carrier tape having a sealing surface perpendicular to the first axis, and a recess that is recessed from the sealing surface in the first direction and accommodates the multilayer ceramic capacitor; and
a top tape that is attached to the sealing surface and covers the recess.

6. A circuit board comprising:
the multilayer ceramic capacitor according to claim 1; and
a mounting substrate having a mounting surface perpendicular to the first axis, and a connection electrode provided on the mounting surface and connected to the external electrode of the multilayer ceramic capacitor through solder.

7. A multilayer ceramic capacitor that has a dimension in a first direction along a first axis equal to or greater than 1.3 times a dimension in a second direction along a second axis orthogonal to the first axis, and is configured to be mounted on a mounting surface perpendicular to the first axis, the multilayer ceramic capacitor comprising:
a ceramic body having a pair of main surfaces perpendicular to the first axis, an end surface perpendicular to a third axis orthogonal to the first axis and the second axis, and a plurality of internal electrodes that contain Ni as a main component, are stacked in the second direction, and are led out to respective connection ends on the end surface; and
an external electrode that contains Cu as a main component and covers the end surface,
wherein the plurality of internal electrodes include outer-side internal electrodes located in both outer sides in the second direction and inner-side internal electrodes located in an inner side in the second direction, and
wherein respective distances from the pair of main surfaces at the connection end of each of the outer-side internal electrodes are larger than respective distances from the pair of main surfaces in a central portion in a third direction along the third axis of each of the inner-side internal electrodes.

8. The multilayer ceramic capacitor according to claim 7, wherein each of the internal electrodes has larger distances from the pair of main surfaces at the connection end than in a central portion in the third direction thereof.

9. The multilayer ceramic capacitor according to claim 8, wherein respective distances from the pair of main surfaces of each of the outer-side internal electrodes are larger than the respective distances from the pair of main surfaces in the central portion in the third direction of each of the inner-side internal electrodes throughout each of the outer-side internal electrodes in the third direction.

10. The multilayer ceramic capacitor according to claim 7, wherein the respective distances from the pair of main surfaces at the connection end of each of the outer-side internal electrodes are larger than respective distances from the pair of main surfaces at the connection end of each of the inner-side internal electrodes.

11. A package comprising:
the multilayer ceramic capacitor according to claim 7;
a carrier tape having a sealing surface perpendicular to the first axis, and a recess that is recessed from the sealing surface in the first direction and accommodates the multilayer ceramic capacitor; and
a top tape that is attached to the sealing surface and covers the recess.

12. A circuit board comprising:
the multilayer ceramic capacitor according to claim 7; and
a mounting substrate having a mounting surface perpendicular to the first axis, and a connection electrode provided on the mounting surface and connected to the external electrode of the multilayer ceramic capacitor through solder.
